(19) United States
(12) Patent Application Publication
(10) Pub. No.: US 2009/0046424 A1
(43) Pub. Date: Feb. 19, 2009

(54) Fan adapter

(75) Inventors: Rui Li, Shanhai City (CN); Tsai-Kuei Cheng, Taipei City (TW)

Correspondence Address: Edwards Angell Palmer & Dodge LLP, P.O. Box 55874, Boston, MA, 02205, US

(73) Assignee: Inventec Corporation, Taipei City (TW)

(21) Appl. No.: 12/008,454

(22) Filed: Jan. 11, 2008

(30) Foreign Application Priority Data
Aug. 13, 2007 (TW) 096129798

(51) Int. Cl. H05K 7/20

(52) U.S. Cl. 361/695

(57) ABSTRACT

This invention provides a fan adapter for electrically connecting a circuit board and a fan connection port. The circuit board has at least a fan pulse width modulation signal node, a first fan waveform feedback signal node, a fan power input signal node, a fan power output signal node, and a second fan waveform feedback signal node. The fan adapter includes a base and first to fifth electrical pins disposed on the base and equidistantly spaced apart in sequence, wherein the first to fifth electrical pins respectively have one end electrically connected to the fan pulse width modulation signal node, the first fan waveform feedback signal node, the fan power input signal node, the fan power output signal node, and the second fan waveform feedback signal node of the circuit board respectively, and respectively have the other end electrically connected to the fan connection port, thereby allowing a single fan adapter to be fit for use with various types of fan connection ports and to control conjoined fans or two fans.

### BACKGROUND OF THE INVENTION

1. Field of the Invention

The present invention relates generally to a fan adapter, and more particularly to a fan adapter capable of being electrically connected to various types of fan connection ports.

2. Description of Related Art

The temperature of electronic component, for example CPU or IC is higher and higher during operation, resulting in instability or shutdown of the electronic component. Hence, heat-dissipation is important for electronic components.

To solve the above-mentioned problem and effectively dissipate the heat generated from electronic components, a heat sink or fan is assembled to an electronic component. Thus the heat generated by the electronic component is conducted to the heat sink or dissipated via the fan.

Generally, a fan mounted in a computer for heat dissipation is electrically connected to a circuit board through a fan adapter, wherein the fan adapter at least includes a power signal. In other words, the fan has a fan connection port electrically connected to the fan adapter such that the fan can obtain electrical power for operation. Currently, there are various types of fan connection ports such as three-pin connection ports, four-pin connection ports or five-pin connection ports. There are different number of pins and different transmission properties of fan connection ports for different types of fans.

Accordingly, manufacturers have different standards of fan adapters for different types of fans and thus a type of fan adapters can only be electrically connected to a specific type of fans rather than other types of fans. In addition, different motherboards may be disposed in different cases so as to form different computer types and different computer types have different requirements for heat dissipation, such that various fan types are required. Thus, various fan adapters are correspondingly assembled and electrically connected to the corresponding fan connection ports, resulting in complicated assembly processes.

Therefore, there is a need to provide a fan adapter that can be electrically connected to various types of fan connection ports so as to avoid the above-mentioned drawbacks.

### SUMMARY OF THE INVENTION

According to the above drawbacks, an objective of the present invention is to provide a fan adapter for electrically connecting a circuit board and various types of fan connection ports.

Another objective of the present invention is to provide a fan adapter for increasing convenience for use.

A further objective of the present invention is to provide a fan adapter for controlling conjoined fans or two fans at the same time.

In order to attain the above and other objectives, the present invention provides a fan adapter for electrically connecting a circuit board and a fan connection port, wherein the circuit board at least includes a fan pulse width modulation signal node, a first fan waveform feedback signal node, a fan power input signal node, a fan power output signal node, and a second fan waveform feedback signal node. The fan adapter includes a base and first to fifth electrical pins disposed on the base and equidistantly spaced apart in sequence, wherein the first to fifth electrical pins respectively have one end electrically connected to the fan pulse width modulation signal node, the fan power input signal node, the fan power output signal node, the first fan waveform feedback signal node, and the second fan waveform feedback signal node of the circuit board, and respectively have the other end electrically connected to the fan connection port, thereby allowing the fan adapter to be fit for use with various types of fan connection ports.

Moreover, the fan connection port has a first positioning portion and the fan adapter has a second positioning portion disposed on the base and corresponding to the first positioning portion, thereby facilitating coupling between the fan connection port and the fan adapter.

The fan connection port is a five-hole connection port having in sequence a fan pulse width modulation signal input pin, a first fan waveform feedback signal output pin, a fan power input signal input pin, a fan power output signal output pin, and a second fan waveform feedback signal output pin. Alternatively, the fan connection port can be a four-hole connection port having in sequence a fan pulse width modulation signal input pin, a first fan waveform feedback signal output pin, a fan power input signal input pin and a fan power output signal output pin, or a three-hole connection port having in sequence a first fan waveform feedback signal output pin, a fan power input signal input pin and a fan power output signal output pin.

Compared with the prior art, the present invention provides a fan adapter having five electrical pins arranged in a specific order and a second positioning portion so as to facilitate coupling of different types of fan connection ports with the fan adapter and allow the fan adapter to be fit for use with various types of fan connection ports. In addition, the present invention eliminates the needs of assembling various fan adapters for corresponding fan connection ports in the prior art.

### BRIEF DESCRIPTION OF DRAWINGS

FIG. 1A is a schematic view showing a fan adapter applied to a first type of fan connection port according to the present invention;

FIG. 1B is a schematic view showing a fan adapter applied to a second type of fan connection port according to the present invention;

FIG. 1C is a schematic view showing a fan adapter applied to a third type of fan connection port according to the present invention;

FIG. 2 is schematic view showing the assembly of a fan adapter and a fan connection port according to the present invention; and

FIG. 3 is a schematic view showing a fan adapter electrically connected to two fans at the same time according to the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification.

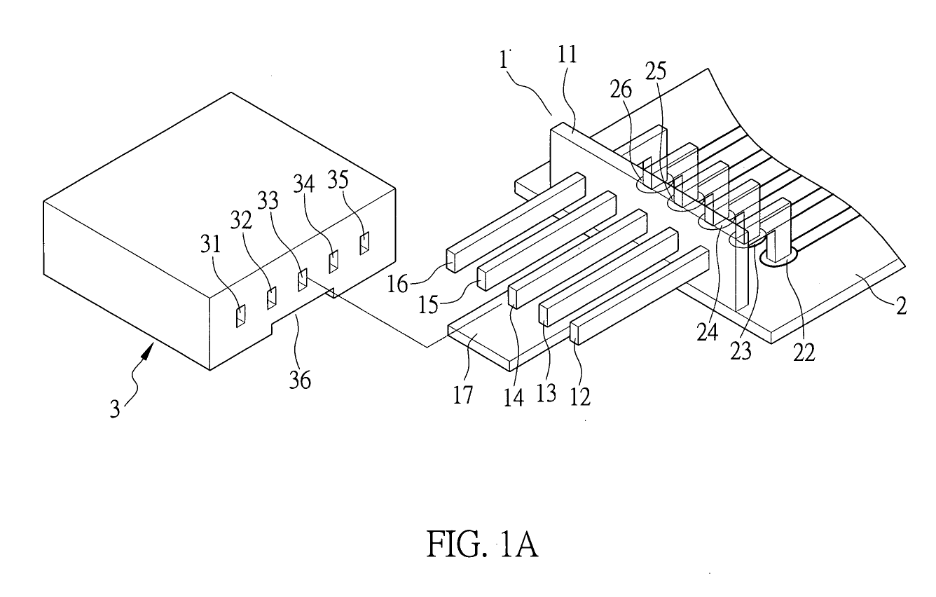

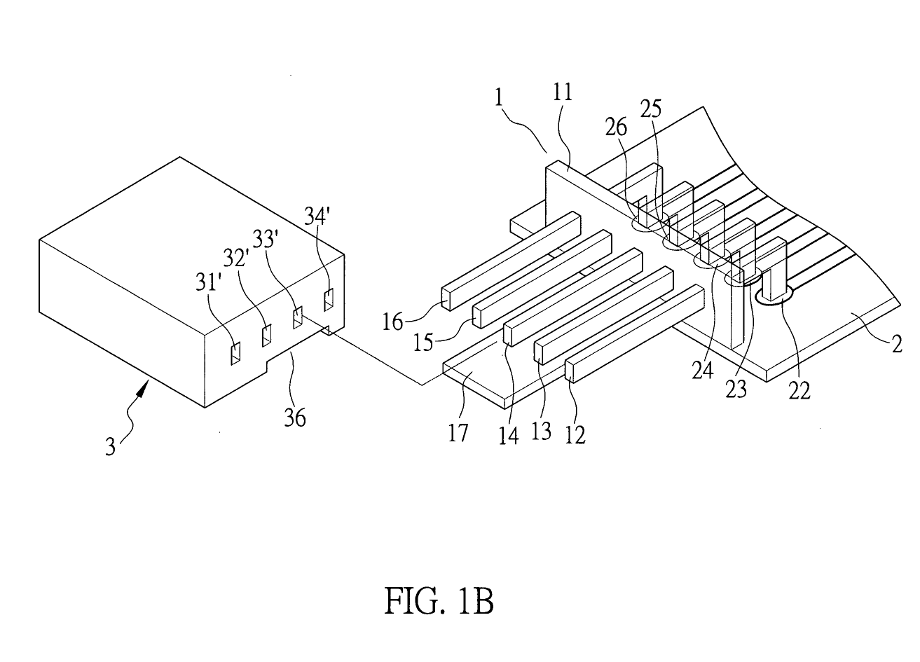

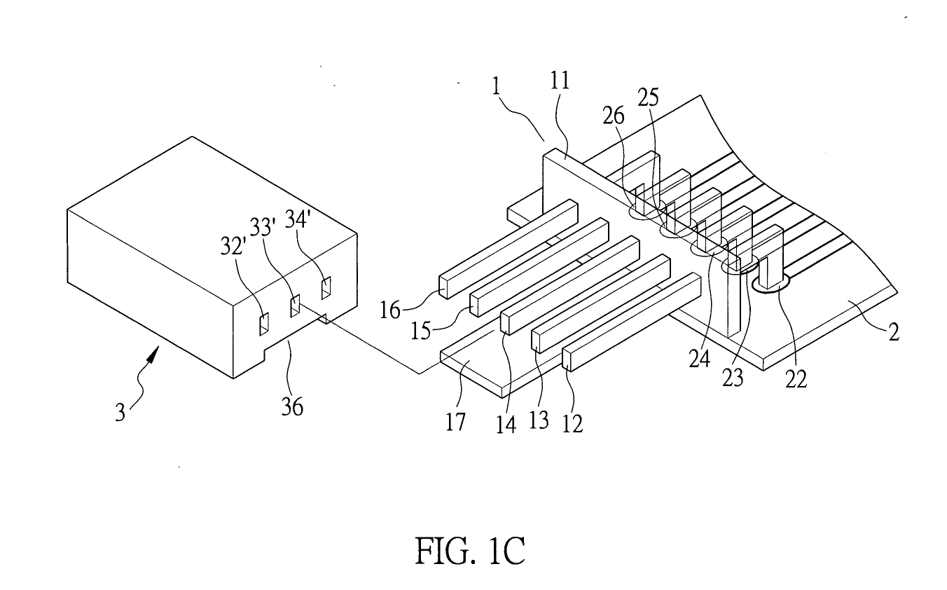

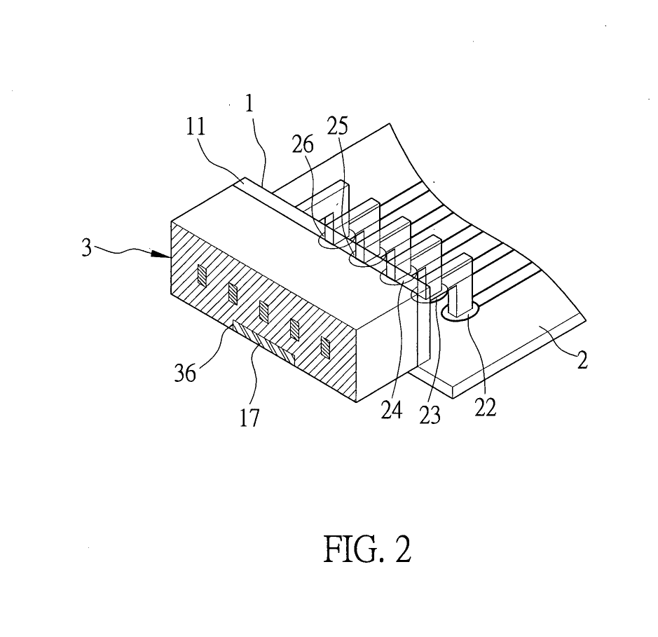

FIGS. 1A to 2 are schematic views showing a fan adapter according to a preferred embodiment of the present invention. It should be noted that in the following embodiment, one end of the fan adapter 1 is electrically connected to a circuit board of an electronic device such as a personal computer or a server, which is a motherboard 2 in the present embodiment, and the other end of the fan adapter 1 is electrically connected to a first type 3, a second type 3′ or a third type 3″ of a fan connection port as shown in FIGS. 1A to 1C. The motherboard 2 at least includes a fan pulse width modulation (PWM) signal node 22, a fan power input signal (+) node 23, a fan power output signal (−) node 24, a first fan waveform feedback signal (FG1) node 25, and a second fan waveform feedback signal (FG2) node 26. The first type of fan connection port 3 is a five-hole fan connection port having in sequence a fan pulse width modulation signal input pin 31, a first fan waveform feedback signal output pin 32, a fan power input signal input pin 33, a fan power output signal output pin 34, and a second fan waveform feedback signal output pin 35. The second type of fan connection port 3′ is a four-hole fan connection port having in sequence a fan pulse width modulation signal input pin 31′, a first fan waveform feedback signal output pin 32′, a fan power input signal input pin 33′ and a fan power output signal output pin 34′. The third type of fan connection port 3″ is a three-hole fan connection port having in sequence a first fan waveform feedback signal output pin 32″, a fan power input signal input pin 33″, and a fan power output signal output pin 34″. In one embodiment, as shown in FIGS. 1A to 1C, the fan connection ports 3, 3′ and 3″ respectively have a first positioning portion 36, 36′ and 36″. For purposes of simplification and clarification, the drawings only show structures related to the present invention.

Referring to FIGS. 1A and 2, the fan adapter 1 of the present invention includes a base 11, first to fifth electrical pins 12, 13, 14, 15, 16 disposed on the base 11 and equidistantly spaced apart in sequence, and a second positioning portion 17 disposed on the base 11.

The first electrical pin 12 is electrically connected to the fan pulse width modulation signal node 22 of the motherboard 2 for receiving and transmitting the fan pulse width modulation signal. The second electrical pin 13 is electrically connected to the first fan waveform feedback signal node 23 of the motherboard 2 for receiving and transmitting the first fan waveform feedback signal. The third electrical pin 14 is electrically connected to the fan power input signal node 24 of the motherboard 2 for receiving and transmitting the fan power input signal. The fourth electrical pin 15 is electrically connected to the fan power output signal node 25 of the motherboard 2 for receiving and transmitting the fan power output signal. The fifth electrical pin 16 is electrically connected to the second fan waveform feedback signal node 26 of the motherboard 2 for receiving and transmitting the second fan waveform feedback signal.

As shown in FIG. 1A, the first to fifth electrical pins 12 to 16 can further be electrically connected to the fan pulse width modulation signal input pin 31, the first fan waveform feedback signal output pin 32, the fan power input signal input pin 33, the fan power output signal output pin 34 and the second fan waveform feedback signal output pin 35 of the first type of fan connection port 3, respectively. As shown in FIG. 1B, the first to fourth electrical pins 12 to 15 can further be electrically connected to the fan pulse width modulation signal input pin 31′, the first fan waveform feedback signal output pin 32′, the fan power input signal input pin 33′ and the fan power output signal output pin 34′ of the second type of fan connection port 3′, respectively. As shown in FIG. 1C, the second to fourth electrical pins 13 to 15 can further be electrically connected to the first fan waveform feedback signal output pin 32″, the fan power input signal input pin 33″ and the fan power output signal output pin 34″ of the third type of fan connection port 3″. Thus, the fan adapter of the present invention can be coupled with various types of fan connection ports.

Preferably, the fan adapter of the present invention further includes a second positioning portion 17 disposed corresponding to the first positioning portion 36 (36′ or 36″ ) of the fan connection ports. Through engagement of the first and second positioning portions, the fan connection port is coupled to the electrical pins of the fan adapter 1, that is, the coupling between the fan connection port and the fan adapter 1 can be easily established by engaging the first positioning portion 36 (36′ or 36″ ) of the fan connection port with the second positioning portion 17 of the fan adapter 1, as shown in FIG. 2, thereby eliminating the need of man-made estimate of the coupling direction. In addition, in the present embodiment, the first positioning portions 36, 36′, and 36″ are, but not limited to concave grooves and the second positioning portion 17 is, but not limited to a protruding bump.

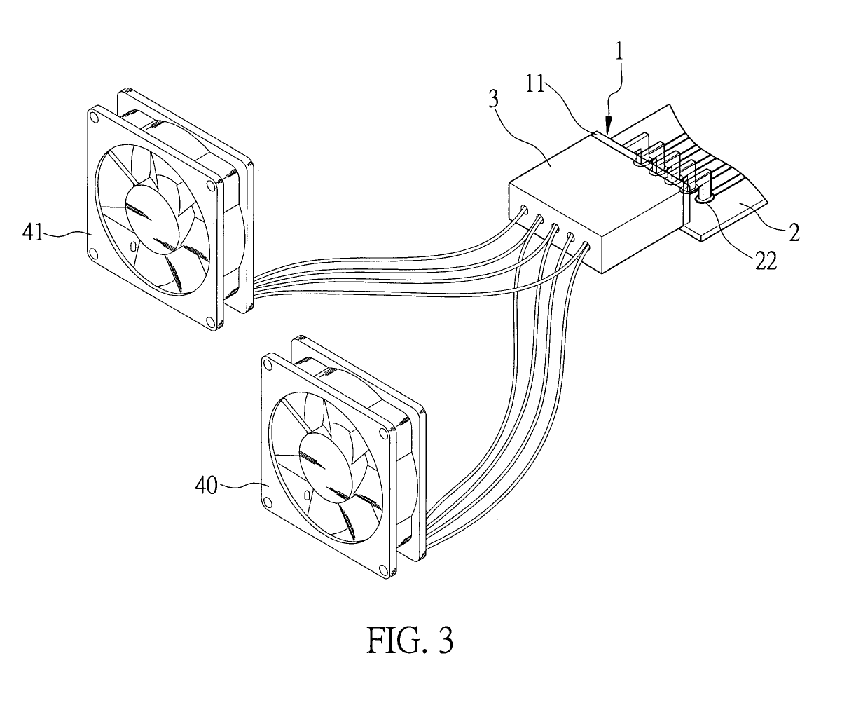

Therefore, the fan adapter according to the present invention includes five pins (PWM/FG1/+/−/FG2) arranged in a specific order and a positioning portion so as to facilitate coupling with a fan having various types of fan connection ports. Further, as shown in FIG. 3, fans 40, 41 (or a conjoined fan) can be controlled at the same time through the FG1 and FG2 electrical pins of the fan adapter. In addition, the present invention eliminates the needs of assembling various types of fan adapters for corresponding fan connection ports in the prior art.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fan adapter for electrically connecting a circuit board and a fan connection port, wherein the circuit board at least comprises a fan pulse width modulation signal node, a fan power input signal node, a fan power output signal node, a first fan waveform feedback signal node, and a second fan waveform feedback signal node, the fan adapter comprising:
a base; and
a first to fifth electrical pins disposed on the base and equidistantly spaced apart in sequence, wherein the electrical pins respectively have one end electrically connected to the fan pulse width modulation signal node, the fan power input signal node, the fan power output signal node, the first fan waveform feedback signal node, and the second fan waveform feedback signal node of the circuit board, and respectively have the other end electrically connected to the fan connection port.

2. The fan adapter of claim 1, wherein the fan connection port has a first positioning portion.

3. The fan adapter of claim 2, further comprising a second positioning portion disposed on the base for engaging with the first positioning portion of the fan connection port.

4. The fan adapter of claim 1, wherein the fan connection port has a fan pulse width modulation signal input pin, a first fan waveform feedback signal output pin, a fan power input signal input pin, a fan power output signal output pin and a second fan waveform feedback signal output pin in sequence.

5. The fan adapter of claim 1, wherein the fan connection port has a fan pulse width modulation signal input pin, a first fan waveform feedback signal output pin, a fan power input signal input pin and a fan power output signal output pin in sequence.

6. The fan adapter of claim 1, wherein the fan connection port has a first fan waveform feedback signal output pin, a fan power input signal input pin and a fan power output signal output pin in sequence.
